(19) United States
(12) Patent Application Publication
(10) Pub. No.: US 2010/0252923 A1
(43) Pub. Date: Oct. 7, 2010

(54) SEMICONDUCTOR DEVICE AND METHOD OF MANUFACTURING SAME

(75) Inventors: Mitsuhisa WATANABE, Tokyo (JP); Keiyo Kusanagi, Tokyo (JP); Koichi Hatakeyama, Tokyo (JP)

Correspondence Address: FOLEY AND LARDNER LLP;SUITE 500, 3000 K STREET NW, WASHINGTON, DC, 20007, US

(73) Assignee: Elpida Memory, Inc.

(21) Appl. No.: 12/726,853

(22) Filed: Mar. 18, 2010

(30) Foreign Application Priority Data
Apr. 7, 2009 (JP) 2009-093060

(51) Int. Cl. H01L 23/498; H01L 21/56

(52) U.S. Cl. 257/737; 438/124; 257/734; 257/E21.504; 257/E23.06

(57) ABSTRACT

A semiconductor device of the present invention includes a semiconductor chip formed with an electrode pad on a front side thereof, a wiring board having a wiring pattern, the wiring board having a front side opposing the back side of the semiconductor chip, a wire for electrically connecting the electrode pad of the semiconductor chip with the wiring pattern of the wiring board, an external terminal arranged on the back side of the wiring board for electrical connection with the electrode pad through the wire and the wiring pattern, and a sealant for fixing the semiconductor chip on the front side of the wiring board so as to form a hollow which is continuous to a portion straddling the entirety of the back side of the semiconductor chip and the front side of the wiring board, and continuous to a portion adjacent to at least one outer peripheral surface of the semiconductor chip except for the back side of the same. The wiring board includes a throughhole in communication with the hollow.

### BACKGROUND OF THE INVENTION

1. Field of the Invention

The present invention relates to a semiconductor device which has a semiconductor chip mounted on a board, and a method of manufacturing the same.

2. Description of the Related Art

In regard to a semiconductor device which employs a BGA (Ball Grid Array) structure related to the present invention, a configuration described in JP2001-044229A (Document 1) has been known, by way of example. This BGA-based semiconductor device comprises a wiring board. The wiring board comprises a predetermined circuit formed on one surface thereof, and a semiconductor chip mounted on the one surface and with a plurality of electrode pads. On the other surface of the wiring board, in turn, a plurality of external terminals are arranged in a lattice form in correspondence to the electrode pads on the semiconductor chip. Then, the electrode pads on the semiconductor chip are electrically connected with the external terminal corresponding to the electrode pads through wires and the like of the wiring board. A sealant is formed on the one surface of the wiring board so as to cover at least the entire semiconductor chip and electric connections between the semiconductor chip and the wiring board.

Such semiconductor devices that have a conventional BGA structure are manufactured, for example, using a MAP (Mold Array Process) method, by collectively sealing a plurality of semiconductor chips disposed on a wiring board.

A semiconductor device that has the BGA structure related to the present invention comprises a semiconductor chip securely adhered on a wiring board using DAF (Die Attach Film), an adhesive or the like. Then, the semiconductor device undergoes a reflow process, where solder balls which serve as external terminals of the wiring board are melted, and is bonded to a mounting board so that the semiconductor device is mounted on the mounting board. A semiconductor device is assembled by securely adhering a semiconductor chip, a wiring board and the like which are made of a plurality of types of materials each having different coefficients of thermal expansion from one another, so that the entire semiconductor device suffers from warpage due to a rise in temperature of the semiconductor device. As a result, stress is applied to external terminals bonded on a mounting board. This stress causes the external terminals to break, the external terminals to peel off from the mounting board, and other phenomena. For this reason, the electrically connection in the connected state of the semiconductor device and the mounting board is damaged, possibly resulting in degraded reliability of the semiconductor device.

As an action taken to address the foregoing problem, JP11-087414A (Document 2), for example, proposes a structure which includes an elastic member (elastomer) sandwiched between a semiconductor chip and a wiring board in order to alleviate stress which occurs between the semiconductor chip and the wiring board.

JP10-189820A (Document 3), in turn, discloses a structure for preventing a package of a semiconductor device from cracking. In this semiconductor device, a semiconductor chip is mounted, by way of a die bond film, on a board which has a bonding sheet formed with a wiring pattern and throughholes, such that a gap is formed between the die bond film and the bonding sheet in communication with the through holes of the bonding sheet.

The inventors have recognized the following problems. The elastomer, which is used as an elastic material in the configuration of aforementioned Document 2, is a very expensive material, and therefore gives rise to a problem of an increase in the manufacturing cost of semiconductor devices.

On the other hand, in the configuration described in aforementioned Document 3, since a semiconductor chip is directly secured on a board, stress will occur due to the difference in the coefficients of thermal expansion between the semiconductor chip and the board. For this reason, reliability of the semiconductor device can undergo degradation because solder balls, which serve as external terminals, are damaged as described above.

Also, in the configuration described in Document 3, a die bond film is applied on the entire back surface of a semiconductor chip. Thus, if a void occurs between the die bond film and the semiconductor chip, the package is likely to crack during a reflow process for solder balls. Further, due to the employment of the die bond film, this configuration can cause an increase in the manufacturing cost of the semiconductor device.

Moreover, in the configuration described in Document 3, a semiconductor chip is bonded only to wiring metal laminated on a bonding sheet which forms part of the board. Therefore, in this configuration, the wiring metal can be broken because stress intensively acts on the wiring metal which is caused by the effect of thermal history in the reflow process, or by the effect of thermal cycling.

### SUMMARY

The present invention is intended to solve the problems described above.

In one embodiment, there is provided a semiconductor device that includes a semiconductor chip formed with an electrode pad on one surface thereof, a wiring board having a wiring pattern, and having one surface opposing the other surface of the semiconductor chip, a connection member for electrically connecting the electrode pad of the semiconductor chip with the wiring pattern of the wiring board, and an external terminal arranged on the other surface of the wiring board for electrical connection with the electrode pad through the connection member and the wiring pattern. The semiconductor device also comprises a fixing member for fixing the semiconductor chip on the one surface of the wiring board so as to form a hollow which is continuous to a portion straddling between the entirety of the other surface of the semiconductor chip and the one surface of the wiring board, and to a portion adjacent to at least one outer peripheral surface of the semiconductor chip except for the other surface of the same. Also, the wiring board includes a throughhole that communicates with the hollow.

The semiconductor device of the present invention configured as described above comprises the hollow which is continuous to a portion straddling the entirety of the other surface of the semiconductor chip and the one surface of the wiring board, and to a portion adjacent to at least one outer peripheral surface of the semiconductor chip except for the other surface of the same, thereby eliminating an area on which the entirety of the other surface of the semiconductor chip adheres to the one surface of the wiring board, and reducing the area on which the outer peripheral surfaces of the semiconductor chip, except for the other surface, adhere to the fixing member. Accordingly, no stress will occur between the other surface of the semiconductor chip and the one surface of the wiring board, and stress is alleviated if it occurs between the outer peripheral surfaces of the semiconductor chip and the one surface of the wiring board through the fixing member and between the semiconductor chip and the fixing member. Otherwise, the occurrence of warpage in a semiconductor device, that is caused by the difference in the coefficients of thermal expansion between the semiconductor chip, wiring board, and the fixing member, is prevented. Also, the hollow communicates with the throughhole of the wiring board, so that even if air within the hollow expands due to a rise in the temperature of the semiconductor device during a reflow process or a semiconductor device mounting process, the expanded air can be allowed to escape to the outside of the wiring board through the throughhole. Consequently, a crack in the package of the semiconductor device can be prevented by the expanded air within the hollow. These advantages are conducive to improvements in reliability of the semiconductor device. For reference, the “one surface,” as used in the present invention, refers to any of surfaces, and the “other surface” refers to a different surface other than the one surface.

In conclusion, according to the present invention, the reliability of the semiconductor device can be improved.

### BRIEF DESCRIPTION OF THE DRAWINGS

The above features and advantages of the present invention will become more apparent from the following description of certain preferred embodiments taken in conjunction with the accompanying drawings, in which:

FIG. 1 is a plan view showing a semiconductor device according to a first embodiment from the back side of a wiring board;

FIG. 2 is a cross-sectional view showing the semiconductor device according to the first embodiment;

FIG. 3 is a cross-sectional view showing the semiconductor device according to the first embodiment when it is mounted on a mounting board;

FIG. 4 is a plan view for describing a process for manufacturing the semiconductor device according to the first embodiment;

FIG. 5A is a cross-sectional view for describing a step of manufacturing the semiconductor device according to the first embodiment;

FIG. 5B is a cross-sectional view for describing a step of manufacturing the semiconductor device according to the first embodiment;

FIG. 5C is a cross-sectional view for describing a step of manufacturing the semiconductor device according to the first embodiment;

FIG. 5D is a cross-sectional view for describing a step of manufacturing the semiconductor device according to the first embodiment;

FIG. 5E is a cross-sectional view for describing a step of manufacturing the semiconductor device according to the first embodiment;

FIG. 5F is a cross-sectional view for describing a step of manufacturing the semiconductor device according to the first embodiment;

FIG. 6 is a plan view showing a wire bonding process in a method of manufacturing the semiconductor device according to the first embodiment;

FIG. 7 is a plan view showing a resin sealing process in the method of manufacturing the semiconductor device according to the first embodiment;

FIG. 8 is a cross-sectional view showing another configuration of the semiconductor device according to the first embodiment;

FIG. 9 is a plan view showing a semiconductor device according to a second embodiment from the back side of a wiring board;

FIG. 10 is a cross-sectional view showing the semiconductor device according to the second embodiment;

FIG. 11 is a cross-sectional view for describing a process for manufacturing the semiconductor device according to the second embodiment; and

FIG. 12 is a cross-sectional view showing a semiconductor device according to a third embodiment.

### DETAILED DESCRIPTION OF THE EXEMPLARY EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purpose.

### First Embodiment

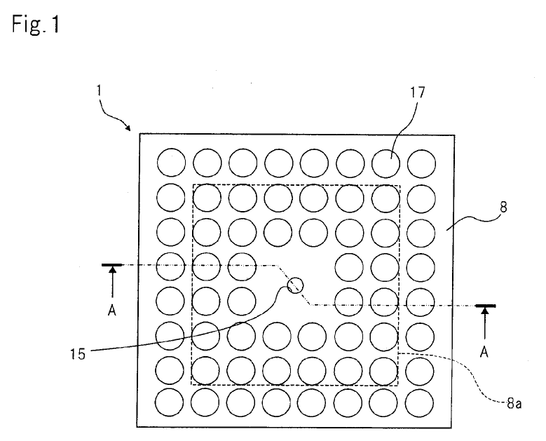

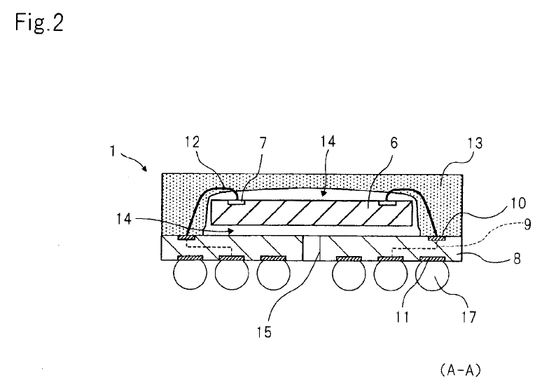

FIG. 1 is a plan view showing a semiconductor device according to a first embodiment from the back side of a wiring board. FIG. 2 is a cross-sectional view showing the semiconductor device according to the first embodiment. The semiconductor device according to the first embodiment is, for example, a semiconductor device that has BGA structure.

As shown in FIGS. 1 and 2, semiconductor device 1 of the first embodiment comprises semiconductor chip 6 which is formed in the shape of a substantially rectangular plate. A predetermined circuit is formed on one main surface (hereinafter called the “front side”), as one surface of semiconductor chip 6. A plurality of electrode pads 7 are also formed, for example, in an outer peripheral zone of the front side of semiconductor chip 6. Also, though not shown, an insulating protective film is formed on the front side of semiconductor chip 6 except in the area of electrode pads 7, such that the protective film protects the circuit formation surface of semiconductor chip 6.

Also, below the other main surface of semiconductor chip 6 (hereinafter called the “back side”) as the other surface, wiring board 8 is disposed. Wiring board 8 is formed with predetermined wiring pattern 9 as conducting means. Wiring board 8 employed herein is a laminate board which is formed in the shape of a substantially rectangular plate and is made of an insulating material, for example, glass epoxy or the like. Wiring board 8 is formed with a semiconductor chip mounting area 8a on one main surface thereof (hereinafter called the “front side”) as one surface. This semiconductor chip mounting area 8a is formed with a plurality of connection pads 10 in an outer peripheral zone thereof as connections corresponding to electrode pads 7 of semiconductor chip 6 mounted on wiring board 8. A plurality of lands 11 are formed on the other main surface (hereinafter called the “back side”) of wiring board 8 as the other surface.

Electrode pads 7 of semiconductor chip 6 are connected with connection pads 10 of wiring board 8 corresponding to electrode pads 7 through wires 12 as connection members made of a conductive material, for example, Au or the like. In this way, electrode pads 7 of semiconductor chip 6 are electrically connected with lands 11 corresponding to electrode pads 7 through wiring pattern 9 on wiring board 8.

Wiring board 8 is formed with sealant 13 on the front side as a fixing member made of a thermosetting resin such as epoxy resin. Sealant 13 is formed to cover at least the front side of semiconductor chip 6 and wires 12 for electrically connecting wiring board 8 with semiconductor chip 6, respectively.

Hollow 14 is also defined to be continuous to a portion which straddles the entire back side of semiconductor chip 6 and the front side of wiring board 8 and to a portion adjacent to the entire outer peripheral surfaces of semiconductor chip 6 except for the back side. Stated another way, semiconductor chip 6 is supported within hollow 14 by a plurality of wires 12 which suspend semiconductor chip 6.

Consequently, the front side of wiring board 8 opposes the back side of semiconductor chip 6, set apart therefrom, with hollow 14 interposed therebetween. This hollow 14 serves as a stress alleviation layer for alleviating stress which can occur between semiconductor chip 6 and wiring board 8.

Specifically, hollow 14 is formed to have a portion adjacent to and parallel to the back side of semiconductor chip 6 whose size is adjusted to be equal to or larger than the area of the back side of semiconductor chip 6, as shown in FIG. 2. According to this size adjustment, since the entire back side of semiconductor chip 6 is spaced apart from the front side of wiring board 8 by hollow 14, stress can be more effectively alleviated, if generated between the back side of semiconductor chip 6 and the front side of wiring board 8, when the temperature of semiconductor device 1 rises, for example, in a reflow process for mounting.

In addition, hollow 14 is formed to be continuous from the back side of semiconductor chip 6 to a portion adjacent to the entire outer peripheral surfaces of semiconductor chip 6 to define one space. Accordingly, when the temperature of semiconductor device 1 rises during mounting, hollow 14 can effectively alleviate stress which occurs between the outer peripheral surface of semiconductor chip 6 except for the back side thereof and the front side of wiring board 8 through sealant 13, and stress which occurs between semiconductor chip 6 and sealant 13.

In essence, semiconductor device 1 is configured to effectively prevent stress which acts on either semiconductor chip 6 or wiring board 8 from being transmitted to the other through the back side of semiconductor chip 6, and through the entire outer peripheral surfaces of semiconductor chip 6 except for the back side of semiconductor chip 6, by hollow 14 included in semiconductor device 1 to cover entire semiconductor chip 6.

Also, hollow 14 has a boundary with sealant 13, formed in a curved surface, without corners formed on an inner surface of sealant 13. As such, it is possible to prevent stress from concentrating on a corner of the inner surface of sealant 13, thus further improving the reliability of semiconductor device 1.

Further, throughhole 15 is formed through the area of semiconductor chip mounting area 8a of wiring board 8. Throughhole 15 is positioned at one site, for example, in a central region of semiconductor chip mounting area 8a, and is in communication with hollow 14. Stated another way, hollow 14 is formed to be continuous to the back side of wiring board 8 through throughhole 15. Because communicating throughhole 15 communicates with hollow 14, air within hollow 14 is smoothly discharged to the outside from throughhole 15 even if the temperature of semiconductor device 1 rises to cause the air to expand within hollow 14. Consequently, a crack in the semiconductor device 1 can be prevented.

Notably, throughhole 15 is only required to be in communication with hollow 14, and may therefore be formed at another position of wiring board 8. Alternatively, a plurality of throughholes 15 may be formed in another configuration. Further, throughhole 15 may vary, as required, with respect to the diameter, the shape of the opening, and the like. However, since foreign substances may possibly intrude into hollow 14 from throughhole 15, throughhole 15 can have a larger effect in preventing foreign substances from intruding into hollow 14, when it is formed to have an opening of a relatively small area, or when it is formed to bend in the middle in the depth direction.

Further, since a plurality of lands 11 are arranged in a lattice form on the back side of wiring board 8, throughhole 15 is advantageously positioned in a central region of wiring board 8, for example, at the center of semiconductor chip mounting area 8a because throughhole 15 thus positioned will not prevent routing of wiring pattern 9, and permits a larger number of connection pads 10 to be arranged on wiring board 8.

Also, a plurality of external terminals 17 are formed on lands 11 of wiring board 8. A ball made of a conductive material, for example, solder or the like is mounted on land 11 through flux, and a reflow process is performed to melt the ball so that external terminal 17 is formed on land 11 with the ball.

Also, adhesive member 18 is applied to a region on the front side of wiring board 8 except for throughhole 15 within hollow 14. Adhesive member 18 employed herein is a material which keeps a predetermined adhesive strength, for example, at temperatures up to approximately 160° C., and evaporates at temperatures equal to or higher than 200° C. Adhesive member 18 is made, for example, of a film material which contains cyclic olefin-based resin blended with epoxy-based resin so as to achieve predetermined characteristics. By heating adhesive member 18 to 200° C. or higher after the formation of sealant 13, adhesive member 18 is removed to the outside of wiring board 8 from throughhole 15, thereby forming hollow 14.

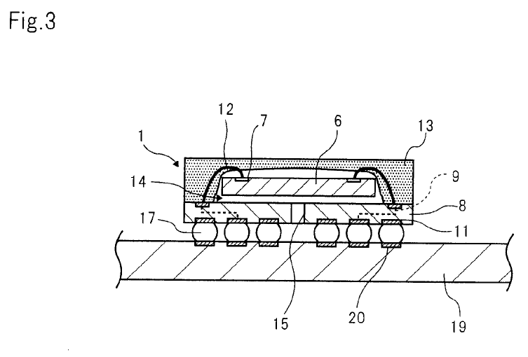

Semiconductor device 1 configured as described above undergoes a reflow process, when it is mounted, where external terminals 17 are melted, and as shown in FIG. 3, a plurality of external terminals 17 are connected to a plurality of lands 20 of mounting board 19, respectively, so that semiconductor device 1 is mounted on mounting board 19. Mounting board 19 employed herein is, for example, a mother board or a modular component board.

In this way, the semiconductor device according to this embodiment comprises semiconductor chip 6 having electrode pads 7 formed on the front side (one surface); wiring board 8 having wiring pattern 9 with its one surface (front side) opposing the back side (the other surface) of semiconductor chip 6; wires 12 (connection members) for electrically connecting electrode pads 7 of semiconductor chip 6 with wiring pattern 9 of wiring board 8; external terminals 17 disposed on the back side (the other surface) of wiring board 8 and electrically connected to electrode pads 7 through wires 12 (connection members) and wiring pattern 9; and sealant 13 (fixing member) for fixing semiconductor chip 6 on the front side (one surface) of wiring board 8 such that hollow 14 is formed to be continuous to a portion which straddles between the entire back side (the other surface) of semiconductor chip 6 and the front side (one surface) of wiring board 8 and to a portion which is adjacent to at least one outer peripheral surface except for the back side (the other surface) of semiconductor chip 6. Wiring board 8 also comprises throughhole 15 in communication with hollow 14.

With this configuration, the entire back side of semiconductor chip 6 is not adhered to the front side of wiring board 8, and the outer peripheral surfaces of semiconductor chip 6 except for the back side are adhered to sealant 13 with a reduced area. Consequently, no stress will occur between the back side of semiconductor chip 6 and the front side of wiring board 8, and stress will be alleviated, if they occur between the outer peripheral surfaces of semiconductor chip 6 and the front surface of wiring board 8 through sealant 13, and between semiconductor chip 6 and sealant 13. As a result, the occurrence of warpage, which is caused by the difference in the coefficients of thermal expansion between semiconductor chip 6, wiring board 8, and sealant 13, can be prevented.

Also, hollow 14 is formed to be in communication with throughhole 15 of wiring board 8. Therefore, when air within hollow 14 expands due to a rise in temperature of semiconductor device 1 in a reflow process for applying the solder balls or a reflow process for mounting semiconductor device 1, the expanded air can be allowed to escape from throughhole 15 to the outside of wiring board 8. Thus, a crack in the package of the semiconductor device caused by the expansion of air within hollow 14 can be prevented from occurring in semiconductor device 1.

According to the foregoing configuration, the reliability of semiconductor device 1 can be improved. Also, since this embodiment does not employ any expensive material such as elastomer, semiconductor device 1 can alleviate stress occurring between semiconductor chip 6 and wiring board 8 at a relatively low cost.

Also, in this embodiment, since hollow 14 borders sealant 13 with a curved boundary surface, stress can be prevented from concentrating on a corner on an inner surface of sealant 13. Thus, by applying this embodiment to semiconductor device 1, the reliability of this device can be further improved.

Particularly, when DRAM (Dynamic Random Access Memory) is employed as semiconductor chip 6, stress on semiconductor chip 6 can be reduced by the action of hollow 14, as described above, so that a deterioration of refresh characteristics in semiconductor device 1 can prevent and so that the refresh characteristics can be improved. Notably, this embodiment may also be applied, for example, to a semiconductor device which includes a sensor unit, and a semiconductor chip which includes movable features such as MEMS (Micro-Electro-Mechanical System). (Method of Manufacturing Semiconductor Device According to First Embodiment)

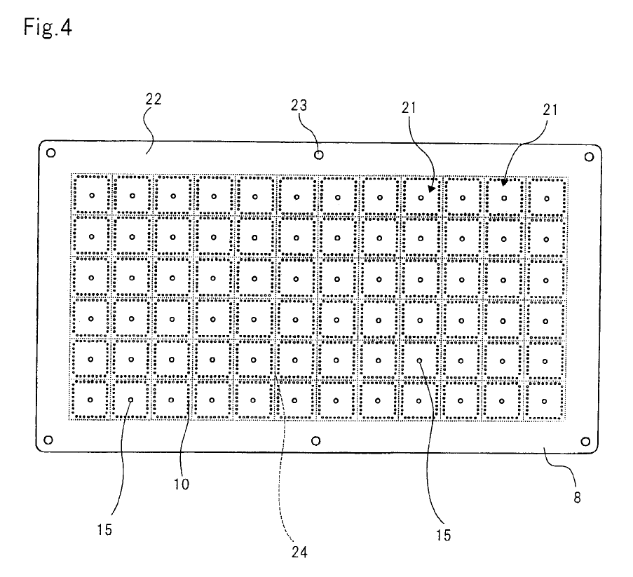

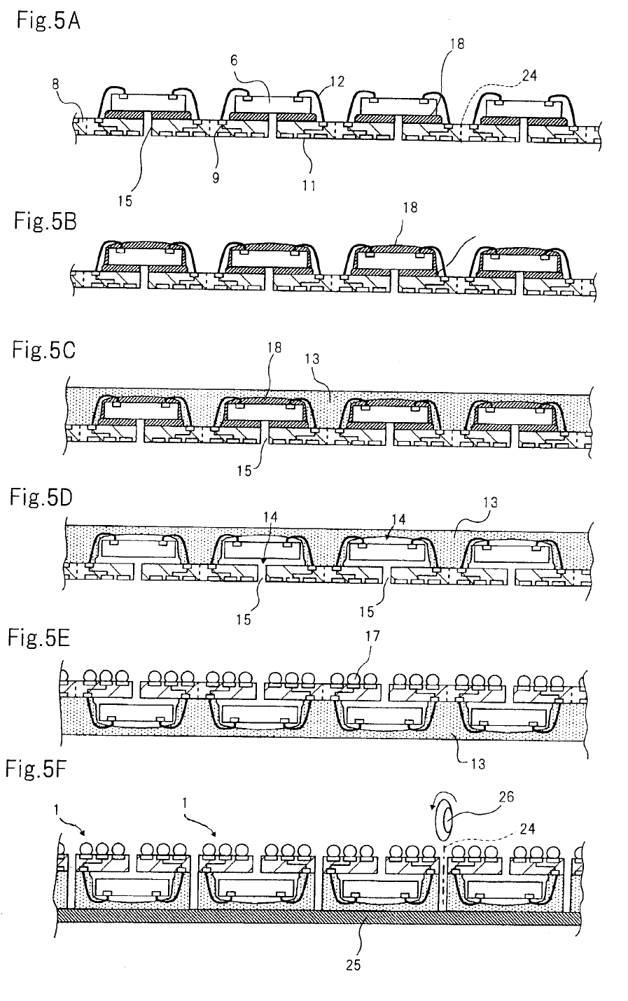

FIG. 4 is a plan view for describing a method of manufacturing the semiconductor device according to the first embodiment. FIGS. 5A-5F are cross-sectional views for describing steps of manufacturing the semiconductor device according to the first embodiment. In the following, a method of manufacturing the semiconductor device according to the first embodiment will be described with reference to the drawings.

First, a semiconductor wafer for use in the method of manufacturing the semiconductor device is provided by forming a silicon ingot, for example, by a single-crystal pull-up method, slicing the silicon ingot into discoidal substrates, and forming a desired circuit and electrode pads 7 on the front side of a substrate through several processes such as diffusion.

Though not shown, the semiconductor wafer is transferred to a dicing unit to undergo the dicing process. In the dicing process, the semiconductor wafer is securely adhered to a UV tape that is provided with an adhesive material which characteristically exhibits adhesive strength that becomes lower when it is irradiated with ultraviolet (UV) rays. In this state, the semiconductor wafer is ground along dicing areas positioned between adjacent semiconductor chips 6, and diced into individual semiconductor chips 6 by a dicing blade which rotates at high speeds. After dicing, the UV tape is irradiated with UV rays to reduce the adhesive strength of the UV tape. In this state, semiconductor chips 6 are pushed up from below the UV tape to peel off semiconductor chips 6 from the UV tape, and semiconductor chips 6 are picked up. In this way, semiconductor chips 6 are produced, each with a plurality of electrode pads 7 formed on the front side.

Also, wiring board 8 for use in this embodiment is processed according to a MAP method, where a unit pattern is created in the following manner.

The unit pattern of wiring board 8, i.e., one wiring board 8 which forms part of semiconductor device 1, is in a substantially rectangular shape, by way of example. As shown in FIG. 1, semiconductor chip mounting area 8a is formed in a substantially central area on the front side of wiring board 8. A plurality of connection pads 10 are arranged in an outer peripheral zone of semiconductor chip mounting area 8a. Connection pads 10 are formed in correspondence to electrode pads 7 of semiconductor chip 6 which is to be mounted on wiring board 8. Also, a plurality of lands 11 are arranged on the back side of wiring board 8. Lands 11 correspond to electrode pads 7 of semiconductor chip 6, and are electrically connected with connection pads 10 through wiring pattern 9. Lands 11 are arranged, for example, at predetermined intervals in a lattice form. Throughhole 15 is also pierced substantially at the center of semiconductor chip mounting area 8a on wiring board 8, extending therethrough from the front side to the back side.

Though not particularly limited, in the configuration of the board shown in FIG. 4, the unit patterns of wiring board 8 are arranged in a matrix of six rows and 12 columns. Therefore, a plurality of product formation areas 21, each having one unit pattern, are arrayed on the board, as shown in FIG. 4. Frame 22 having a predetermined width is formed around the periphery of the board on which a plurality of product formation areas 21 are arrayed. Frame 22 comprises a plurality of guide holes 23 which enable transportation and positioning of the board. Dicing lines 24 are drawn along boundaries of each unit pattern on wiring board 8. Eventually, the board, as configured in a manner shown in FIG. 4, is prepared.

As shown in FIG. 5A, semiconductor chip mounting area 8a of wiring board 8 is provided with adhesive member 18 which is made, for example, of a cyclic olefin-based resin material blended with epoxy-based resin, PEG (polyethylene glycol), or the like, so as to achieve predetermined characteristics. A material used for adhesive member 18 is a non-conductive material which maintains a predetermined adhesive strength at temperatures, for example, up to approximately 160° C., and evaporates at temperatures equal to or higher than 200° C. Also, adhesive member 18 may be disposed on semiconductor chip mounting area 8a so as not to block throughhole 15. The size of adhesive member 18 is arranged so that it has an area larger than the area of the back side of semiconductor chip 6. In this way, when adhesive member 18 evaporates in a process, later described, the entire area of the back side of semiconductor chip 6 can be spaced apart from the front side of wiring board 8. Alternatively, adhesive member 18 may be attached on the back side of semiconductor chip 6 instead of the front side of wiring board 8.

Wiring board 8 to which adhesive member 18 has been attached is transferred to a die bonding unit to undergo the die bonding process. In the die bonding process, semiconductor chips 6 are mounted respectively in the areas of a plurality of semiconductor chip mounting areas 8a laid out in a matrix form on wiring board 8. Semiconductor chip 6 is mounted on the front side of wiring board 8 by adhering the back side of semiconductor chip 6 to adhesive member 18 attached to semiconductor chip mounting area 8a, as shown in FIG. 5A. In this event, the opening of throughhole 15 on the front side of wiring board 8 is blocked by the adhesive member 18 and the back side of semiconductor chip 6.

Subsequently, wiring board 8 mounted with semiconductor chips 6 is transferred to a wire bonding unit to undergo the wire bonding process. In the wire bonding process, electrode pads 7 of semiconductor chips 6 mounted on wiring board 8 are electrically connected with connection pads 10 disposed in the outer peripheral zone of wiring board 8, on which semiconductor chip 6 is mounted, using wires 12 which are made of a conductive material, for example, Au or the like, as shown in FIG. 5A. In this way, electrode pads 7 of semiconductor chip 6 are electrically connected with lands 11 corresponding to electrode pads 7 through wires 12 and wiring pattern 9 of wiring board 8. The wire bonding involves ultrasonic thermocompression bonding of one end of wire 12, melted to form a solder ball, onto electrode pad 7 of semiconductor chip 6, using a wire bonding machine, not shown, to connect wire 12 to electrode pad 7. Subsequently, wire 12 is guided to draw a predetermined loop shape, and the other end of wire 12 is connected onto connection pad 10 corresponding to electrode pad 7 through ultrasonic thermocompression bonding. The connection of the other end of wire 12 is followed by cutting a surplus portion of wire 12 extending from this other end.

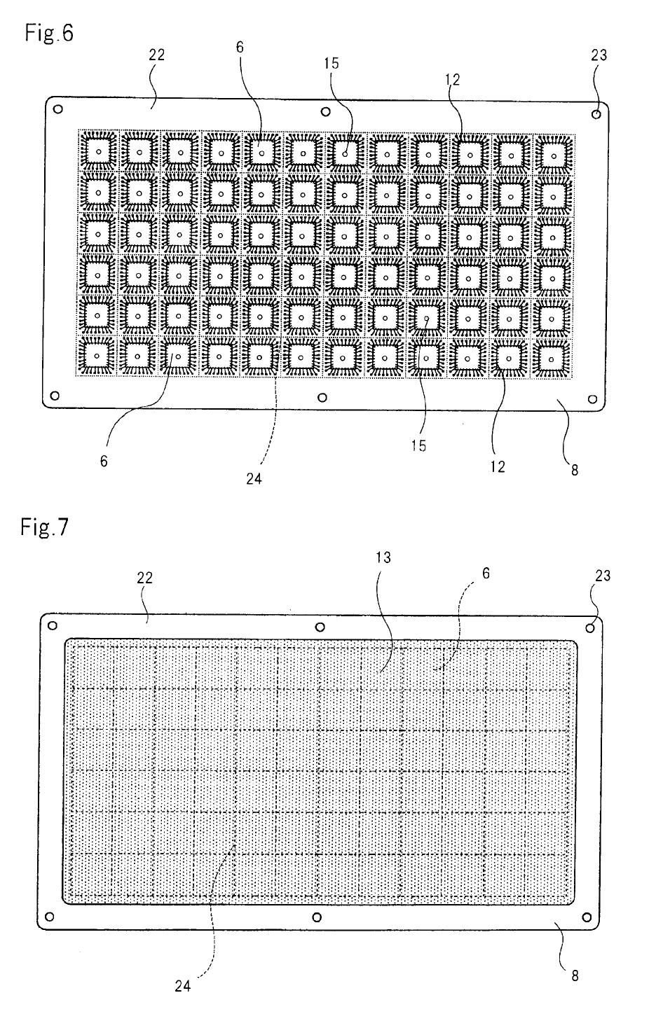

In this way, all of a plurality of electrode pads 7 included in semiconductor chip 6 are wire bonded to all of a plurality of connection pads 10 included in wiring board 8, to complete the structure as shown in FIGS. 5A and 6. Notably, since the wire bonding is performed at temperatures of approximately 150° C., by way of example, adhesive member 18 maintains a predetermined adhesive strength in the wire bonding process. Thus, semiconductor chips 6 are securely held by adhesive member 18, so that wire bonding processing can be accomplished in a satisfactory manner.

After the completion of wire bonding, resulting wiring board 8 undergoes potting of the aforementioned adhesive member 18, as a covering member, onto semiconductor chip 6 mounted on semiconductor chip mounting area 8a of wiring board 8, as shown in FIG. 5B. In this way, semiconductor chip 6 is covered with adhesive member 18 over the entire outer peripheral surfaces thereof except for the back side. In this embodiment, the aforementioned adhesive member 18 is used as the covering member, so that the manufacturing process is simplified by utilizing adhesive member 18 for securely adhering semiconductor chip 6 on the front side of wiring board 8. In this regard, a material employed for the covering member may be a resin material different from adhesive member 18, as required, for example, a resin material which does not have adhesion properties.

Next, wiring board 8 is subjected to a resin sealing process after the entire outer peripheral surfaces of semiconductor chip 6 have been covered with adhesive member 18. In the resin sealing process, a plurality of product formation areas 21 arrayed in a matrix form are collectively sealed with a thermosetting resin such as epoxy resin to form sealant 13 on the front side of wiring board 8 so as to cover at least adhesive member 18 which covers semiconductor chip 6, and wires 12, as shown in FIGS. 5C and 7. In such a resin sealing process, wiring board 8 is clamped using a mold comprised of an upper piece and a lower piece, for example, included in a transfer mold machine, not shown, an epoxy resin is injected into a cavity defined by the upper piece and lower piece from a gate of the mold, and the epoxy resin is thermally cured to form sealant 13. In this event, the opening of throughhole 15 that is pierced through wiring board 8, on the front side of wiring board 8, is blocked by adhesive member 18 and the back side of semiconductor chip 6, as shown in FIG. 5B, such that the epoxy resin for forming sealant 13 is prevented from flowing into throughhole 15.

Subsequently, wiring board 8 formed with sealant 13 is subjected to a process for forming a hollow. In the hollow forming process, wiring board 8 formed with sealant 13 is heated to temperatures equal to or higher than 200° C. to evaporate adhesive member 18, thus discharging adhesive member 18 to the outside of wiring board 8 from throughhole 15, as shown in FIG. 5D. Notably, while the hollow forming process is provided in this embodiment, a reflow process for applying the solder balls, later described, may be set to additionally serve the hollow forming process which involves heating wiring board 8 formed with sealant 13 to temperatures equal to or higher than 200° C.

By thus discharging adhesive member 18 through throughhole 15, hollow 14 is formed to be continuous between the back side of semiconductor chip 6 and the front side of wiring board 8, and to the front side and side surfaces of semiconductor chip 6, which are outer peripheral surfaces of semiconductor chip 6. This hollow 14 serves as stress alleviation layer between the outer peripheral surfaces of semiconductor chip 6 and the front side of wiring board 8.

As described above, hollow 14 is defined to have a size in the direction parallel to the back side of semiconductor chip 6 equal to or larger than the area of the back side of semiconductor chip 6, allowing the entire back side of semiconductor chip 6 to be completely spaced apart from the front side of wiring board 8 by hollow 14. By thus designing hollow 14, it is possible to eliminate stress which would otherwise occur between the back side of semiconductor chip 6 and the front side of wiring board 8.

In addition, since hollow 14 is formed to cover the perimeter, i.e., entire outer peripheral surfaces of semiconductor chip 6, the outer peripheral surfaces of semiconductor chip 6 are completely spaced apart from sealant 13. By thus designing hollow 14, it is possible to prevent, without fail, stress from occurring between the outer peripheral surfaces of semiconductor chip 6 and the front side of wiring board 8, and between the outer peripheral surfaces of semiconductor chip 6 and sealant 13.

This embodiment employs material which evaporates at a predetermined temperature for adhesive member 18, such that adhesive member 18 will be fully discharged to the outside of wiring board 8 through throughhole 15, and will not remain within hollow 14. Alternatively, a material which melts at a predetermined temperature may be employed instead for adhesive member 18, in which case hollow 14 can be formed in a similar manner to the above. Further alternatively, a material which thermally contracts at a predetermined temperature may be employed for the adhesive member, in which case thermally contracted adhesive member 18 may remain, for example, on the outer peripheral surfaces of semiconductor chip 6.

Also, hollow 14 is in communication with throughhole 15 which extends through wiring board 8 from the front side to the back side. Thus, even if the temperature of semiconductor device 1 rises, air expanding within hollow 14 is smoothly discharged to the outside of wiring board 8 from throughhole 15, so that a crack in the package of semiconductor device 1 can be prevented from occurring.

Next, wiring board 8 formed with hollow 14 between semiconductor chip 6 and wiring board 8 is transferred to a soldering ball mount unit to undergo the solder ball mount process. In the ball mount process, conductive balls are mounted on a plurality of lands 11 arranged on the back side of wiring board 8 in a lattice form, as shown in FIG. 5E, to form external terminals 17 in the form of solder balls. The solder ball mount process employs an adsorption mechanism, not shown, which is formed with a plurality of adsorption holes in conformity with the arrangement of lands 11 on wiring board 8, to hold solder balls made, for example, of solder or the like in the adsorption holes. Then, flux is transferred to and formed on the solder balls held in the adsorption holes of the adsorption mechanism, and the solder balls are collectively mounted on a plurality of lands 11 on wiring board 8. After mounting the solder balls, external terminals 17 are formed by performing a reflow process for applying the solder balls.

Subsequently, wiring board 8 formed with external terminals 17 is transferred to a board dicing unit to undergo the board dicing process. In the board dicing process, wiring board 8 is cut and separated along dicing lines 24, as shown in FIG. 5F. In the board dicing process, sealant 13 of wiring board 8 is adhered to dicing tape 25 to support wiring board 8 with dicing tape 25. Wiring board 8 is cut vertically and horizontally along dicing lines 24 by dicing blade 26 to singulate wiring board 8. While wiring board 8 is cut by full cut dicing in this embodiment, each of singulated semiconductor devices 1 is supported by dicing tape 25. After the completion of dicing, each of singulated semiconductor devices 1 is picked up from dicing tape 25 to provide semiconductor devices 1 as shown in FIG. 2. Notably, since wiring boards 8 that are collectively sealed using the MAP method are cut and separated through dicing, semiconductor device 1 is formed such that the side surfaces of wiring boards 8 are flush with the side surfaces of sealant 13, resulting in a satisfactory hexahedral structure.

As described above, the manufacturing method according to this embodiment comprises the steps of providing a semiconductor chip including a plurality of electrode pads 7 arranged on the front side (one surface) thereof; and providing wiring board 8 including wiring pattern 9, semiconductor chip mounting area 8a defined on the front side (one surface), throughhole 15 pierced within semiconductor chip mounting area 8a, and a plurality of lands 11 arranged on the back side (the other surface) thereof. The manufacturing method according to this embodiment also comprises the steps of securely adhering the other surface of semiconductor chip 6 to semiconductor chip mounting area 8a of wiring board 8 with adhesive member 18; electrically connecting electrode pads 7 of semiconductor chip 6 with wiring pattern 9 through wires 12 (connection members); and forming sealant 13 (fixing member) so as to fix semiconductor chip 6 covered with adhesive member 18 (covering member) on the front side (one surface) of wiring board 8. The manufacturing method according to this embodiment further comprises the steps of forming hollow 14 continuous to a portion which straddles the entire back side (the other surface) of semiconductor chip 6 and the front side (one surface) of wiring board 8 and continuous to a portion adjacent to at least one outer peripheral surface of semiconductor chip 6 except for the back side (the other surface) thereof by removing adhesive member 18, which securely adheres semiconductor chip 6 on wiring board 8, to the outside of wiring board 8 through throughhole 15, after the formation of sealant 13 (fixing member); and forming external terminals 17 on lands 11 of wiring board 8. With each of these steps, resulting semiconductor device 1 includes hollow 14 which is extended from the portion that straddles the entire back side (the other surface) of semiconductor chip 6 and the front side (one surface) of wiring board 8 to the portion adjacent to at least one outer peripheral surface of semiconductor chip 6 except for the back side (the other surface) thereof.

According to the manufacturing method of this embodiment, semiconductor device 1, having improved reliability in preventing stress from being transferred to semiconductor chips, can be manufactured at a relatively low cost by alleviating stress, that acts on semiconductor chip 6 or wiring board 8, by the action of hollow 14 without using a relatively expensive elastic material such as elastomer.

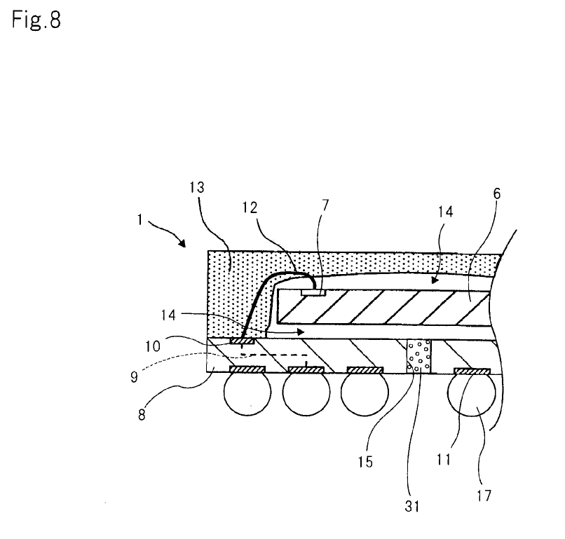

Additionally, semiconductor device 1 may comprise porous material 31 disposed within throughhole 15, as shown in FIG. 8, after the hollow forming process. According to this configuration, semiconductor device 1 may be configured to prevent foreign substances from intruding from the outside into hollow 14 by way of throughhole 15. Further alternatively, an air-permeable sheet member, not shown, may be employed and applied over the opening of throughhole 15 on the back side of wiring board 8, in order to prevent foreign substances from entering hollow 14.

Also, in the embodiment described above, adhesive member 18 is applied over the entire back side of semiconductor chip 6, but adhesive member 18 may be formed in a rectangular frame shape along the outer peripheral edges of semiconductor chip mounting area 8a on wiring board 8, in other words, along the outer peripheral edges of the back side of semiconductor chip 6. Throughhole 15, in turn, is only required to communicate with hollow 14, and can be placed freely at a position other than the center of wiring board 8, for example, at a position at which no wiring pattern 9 exits.

Next, other embodiments will be described with reference to the drawings. In other embodiments, the same component members as those of the first embodiment are designated the same reference numerals, and descriptions thereon are omitted.

### Second Embodiment

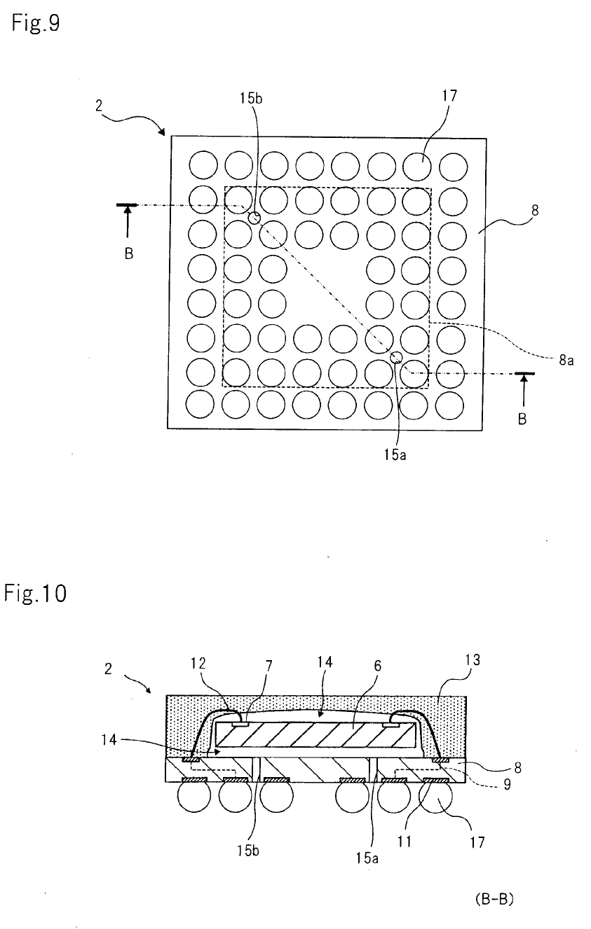

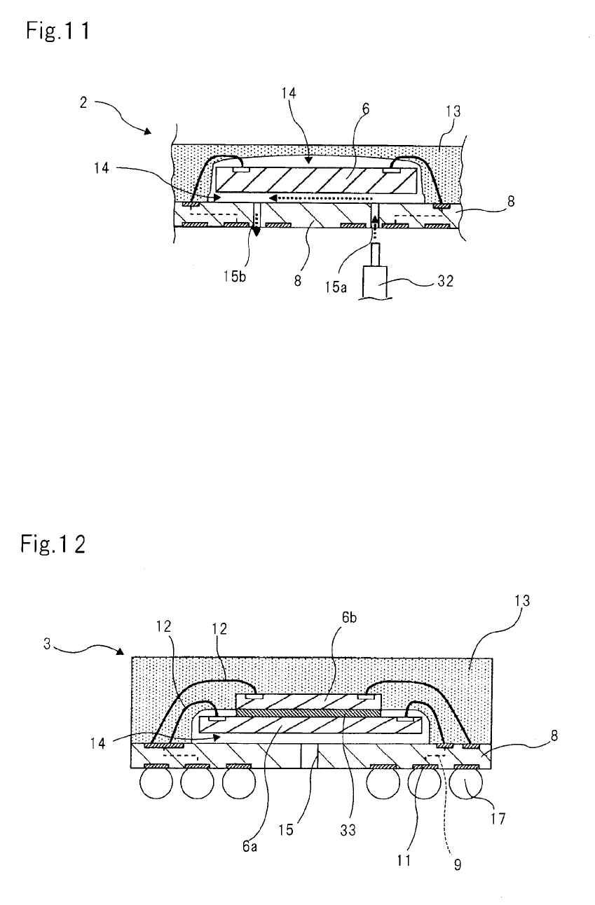

A second embodiment will be described with reference to FIGS. 9, 10, and 11. FIG. 9 is a cross-sectional view showing the structure of a semiconductor device according to the second embodiment, FIG. 10 is a plan view showing the semiconductor device according to the second embodiment from the back side of a wiring board, and FIG. 11 is a cross-sectional view for describing a process for manufacturing the semiconductor device according to the second embodiment.

Semiconductor device 2 according to the second embodiment is configured substantially in a similar manner to the first embodiment, except for two throughholes 15a, 15b which are pierced through wiring board 8 at predetermined positions, as shown in FIG. 9. A description will be given of the configuration of semiconductor device 2 according to the second embodiment, and a method of manufacturing the same.

As shown in FIGS. 9 and 10, two throughholes 15a, 15b are formed through wiring board 8 within semiconductor chip mounting area 8a. Thus, air or inert gas, for example, can be injected from one throughhole 15a of two throughholes 15a, 15b using air supply device 32, as shown in FIG. 11, so that adhesive member 18 evaporated within hollow 14 can be efficiently discharged to the outside of wiring board 8 from the other throughhole 15b. Throughholes 15a, 15b may be formed at different positions within semiconductor chip mounting area 8a. However, throughholes 15a, 15b are preferably pierced at positions near a pair of opposing corners of rectangular semiconductor chip mounting area 8a corresponding to rectangular semiconductor chip 6, for example, positions on diagonal lines of rectangular semiconductor chip mounting area 8a, respectively. According to this configuration, gas within hollow 14 can be smoothly moved from one to the other of throughholes 15a, 15b, and evaporated adhesive member 18 can be efficiently discharged to the outside of wiring board 8. Also, when evaporated or melted adhesive member 18 is discharged to the outside of wiring board 8 from throughhole 15, a larger number of throughholes 15 can advantageously facilitate the discharge.

Alternatively, the throughhole may be formed to bend in the middle in the depth direction, or formed to incline with respect to the thickness direction of wiring board 8. The throughhole thus formed can smoothly discharge evaporated or melted adhesive member 18 from hollow 14 to the outside, and prevent foreign substances from intruding from the outside into hollow 14.

### Third Embodiment

Next, a third embodiment will be described with reference to FIG. 12. FIG. 12 is a cross-sectional view showing the structure of a semiconductor device according to the third embodiment.

While the foregoing embodiments have been described in connection with the configuration which has one semiconductor chip 6 mounted on wiring board 8, semiconductor device 3 according to the third embodiment is configured substantially in a similar manner to the foregoing embodiments, except that two semiconductor chips are placed one on the other, as shown in FIG. 12. A description will be given of the configuration of semiconductor device 3 according to the third embodiment.

As shown in FIG. 12, this embodiment may be applied to MCP (Multi Chip Package) which comprises semiconductor chip 6a supported on wiring board 8 and suspended by wire 12, and additional semiconductor chip 6b mounted on semiconductor chip 6a. In this configuration, additional semiconductor chip 6b is placed on the front side of semiconductor chip 6a surrounded by hollow 14 through DAF 33, and additional semiconductor chip 6b is electrically connected to connection pads 10 of wiring board 8 through wires 12.

While the present invention has been specifically described with reference to embodiments thereof, it should be understood that the present invention is not limited to the foregoing embodiments and can be modified in various manners without departing from the spirit thereof. For example, while the foregoing embodiments have been described in connection with the configuration where a plurality of electrode pads 7 are arranged in an outer peripheral zone on the front side of semiconductor chip 6, the present invention can also be applied to semiconductor chips which differ in the arrangement of electrode pads, for example, a center-pad configuration which comprises electrode pads arranged in a central area on the front side of a semiconductor chip, and the like. Also, while the embodiments have been described in connection with a semiconductor device that has BGA structure to which the present invention is applied, the present invention can also be applied to a semiconductor device that has LGA (Land Grid Array) structure.

It is apparent that the present invention is not limited to the above embodiments, but may be modified and changed without departing from the scope and spirit of the invention.

What is claimed is:

1. A semiconductor device comprising:
a semiconductor chip formed with an electrode pad on one surface thereof;
a wiring board having a wiring pattern, said wiring board having one surface opposing the other surface of said semiconductor chip;
a connection member for electrically connecting the electrode pad of said semiconductor chip with the wiring pattern of said wiring board;
an external terminal arranged on the other surface of said wiring board for electrical connection with said electrode pad through said connection member and the wiring pattern; and
a fixing member for fixing said semiconductor chip on the one surface of said wiring board so as to form a hollow which is continuous to a portion straddling the entirety of the other surface of said semiconductor chip and the one surface of said wiring board, and continuous to a portion adjacent to at least one outer peripheral surface of said semiconductor chip except for the other surface of the same,
wherein said wiring board includes a throughhole in communication with said hollow.

2. The semiconductor device according to claim 1, wherein:
said hollow is formed over entire outer peripheral surfaces of said semiconductor chip.

3. The semiconductor device according to claim 1, wherein:
said throughhole is positioned in a substantially central region on the one surface of said wiring board.

4. The semiconductor device according to claim 1, wherein:
said wiring board includes at least two of said throughholes, and
said two throughholes are positioned near a pair of opposing corners, respectively, of said semiconductor chip in a rectangular shape.

5. The semiconductor device according to claim 1, further comprising:
an air-permeable porous member disposed in said throughhole.

6. The semiconductor device according to claim 1, wherein:
said hollow borders said fixing member with a boundary formed in a curved surface.

7. A semiconductor device comprising:
a semiconductor chip including a plurality of electrode pads arranged on one surface thereof;
a wiring board disposed on a side closer to the other surface of said semiconductor chip, said wiring board having one surface spaced apart from and opposite to the other surface of said semiconductor chip;
a throughhole pierced to extend through said wiring board;
a plurality of connections arranged on the one surface of said wiring board in correspondence to the plurality of electrode pads;
a plurality of external terminals arranged on the other surface of said wiring board;
conducting means for electrically connecting said connections with said external terminals corresponding to said connections, respectively;
connection members for electrically connecting said electrode pads with said connections corresponding to said electrode pads, respectively; and
a fixing member for fixing said semiconductor chip on the one surface of said wiring board so as to form a hollow which is continuous to a portion straddling the entirety of the other surface of said semiconductor chip and the one surface of said wiring board, and continuous to a portion adjacent to at least one outer peripheral surface of said semiconductor chip except for the other surface of the same, and also continuous to the other surface of said wiring board through said throughhole,
wherein said semiconductor device is configured to prevent the transmission of stress distortion, which occurs on one of said semiconductor chip and said wiring board, to the other, said semiconductor chip and said wiring board through the other surface of said semiconductor chip and through at least one outer peripheral surface of said semiconductor chip except for the other surface.

8. The semiconductor device according to claim 7, wherein:
said hollow is formed over entire outer peripheral surfaces of said semiconductor chip.

9. The semiconductor device according to claim 7, wherein:
said throughhole is positioned in a substantially central region on the one surface of said wiring board.

10. The semiconductor device according to claim 7, wherein:
said wiring board includes at least two of said throughholes, and
said two throughholes are positioned near a pair of opposing corners, respectively, of said semiconductor chip in a rectangular shape.

11. The semiconductor device according to claim 7, further comprising:
an air-permeable porous member disposed in said throughhole.

12. The semiconductor device according to claim 7, wherein:
said hollow borders said fixing member with a boundary formed in a curved surface.

13. A method of manufacturing a semiconductor device including a wiring board having a semiconductor chip mounting area defined on one surface, a throughhole pierced within said semiconductor chip mounting area, a land arranged on the other surface, and a wiring pattern electrically connected to said land, and a semiconductor chip having an electrode pad disposed on one surface, said method comprising the steps of:
securely adhering the other surface of said semiconductor chip to said semiconductor chip mounting area with an adhesive member;
electrically connecting said electrode pad of said semiconductor chip with said wiring pattern through a connection member;
covering at least one outer peripheral surface of said semiconductor chip except for the other surface of the same with a covering member;
forming a fixing member so as to fix said semiconductor chip covered with said covering member on the one surface of said wiring board;
removing said adhesive member which securely adheres said semiconductor chip to said wiring board, and said covering member to the outside of said wiring board through said throughhole, after the formation of said fixing member, to form a hollow which is continuous to a portion straddling the entirety of the other surface of said semiconductor chip and the one surface of said wiring board, and continuous to a portion adjacent to at least one outer peripheral surface of said semiconductor chip except for the other surface of the same; and
forming an external terminal on said land of said wiring board.

14. The method of manufacturing a semiconductor device according to claim 13, wherein:
said step of forming a hollow includes melting or evaporating said adhesive member and said covering member.

15. The method of manufacturing a semiconductor device according to claim 13, wherein:
said step of covering with a covering member includes covering entire outer peripheral surfaces of said semiconductor chip except for the other surface of the same with said covering member.

16. The method of manufacturing a semiconductor device according to claim 13, wherein:
said adhesive member includes a material which maintains a predetermined adhesive strength at temperatures up to at least 160° C., and melts or evaporates at temperatures equal to or higher than 200° C.

17. The method of manufacturing a semiconductor device according to claim 13, wherein:
said covering member is made of the same material as said adhesive member.
